(19) United States
(12) Patent Application Publication
(10) Pub. No.: US 2003/0173676 A1
(43) Pub. Date: Sep. 18, 2003

(54) Multi-layered semiconductor device and method of manufacturing same

(75) Inventor: Yasuyoshi Horikawa, Nagano-shi (JP)

Correspondence Address: STAAS & HALSEY LLP, SUITE 700, 1201 NEW YORK AVENUE, N.W., WASHINGTON, DC, 20005, US

(73) Assignee: SHINKO ELECTRIC INDUSTRIES CO., LTD., Nagano (JP)

(21) Appl. No.: 10/375,018

(22) Filed: Feb. 28, 2003

(30) Foreign Application Priority Data
Mar. 12, 2002 (JP) 2002-066349

(51) Int. Cl. H01L 23/48

(52) U.S. Cl. 257/758

(57) ABSTRACT

A semiconductor device includes: a multi-layered wiring substrate in which a multiple wiring pattern layers are laminated through insulating layers. The multi-layered wiring substrate has a first, semiconductor element mounting face and a second face opposite to the first face. A semiconductor element is mounted on and connected to connecting pads on the first face. A chip-capacitor is arranged on and connected to the connecting pads on the second face. An electric power supply circuit includes the chip-capacitor for supplying electric power to the semiconductor element. Conductor paths for electrically connecting the first connecting pads with the second connecting pads are substantially extended vertically and penetrate through the multi-layered wiring substrate through so as to reduce the length of the conductor paths to a minimum, so that the chip-capacitor is located at the opposite side of the semiconductor element.

### BACKGROUND OF THE INVENTION

1. Field of the Invention

The present invention relates to a semiconductor device and method of manufacturing it. More particularly, the present invention relates to a semiconductor device in which electric power is supplied to a semiconductor element, which is mounted on a semiconductor element mounting face formed on one face of a multilayered wiring substrate on which multiple wiring pattern layers are laminated through insulating layers, through an electric power source circuit containing a chip capacitor arranged on the other face of the multilayered wiring substrate. The present invention also relates to a method of manufacturing the semiconductor device.

2. Description of the Related Art

Japanese Unexamined Patent Publication (Kokai) No. 9-260537 discloses a semiconductor device as shown in FIG. 8. In this semiconductor device, the semiconductor element 31 is mounted on the multilayered wiring substrate 340, and an electric power source terminal, grounding terminal and output terminal arranged in the semiconductor element 31 are respectively connected with the corresponding connection pads 370, which are provided on the multilayered wiring substrate, through the solder bumps 330.

In the semiconductor device shown in FIG. 8, in order to stably supply electric power to the semiconductor element 31 in accordance with an enhancement in high integration and high processing speed, there is provided a chip capacitor 32 between the connection pad 370 for supplying electric power and the connection pads 370 for grounding of the multilayered wiring substrate 340. This chip capacitor 32 is mounted on the other face of the multilayered wiring substrate 340, on one face of which the semiconductor element mounting face is formed, in such a manner that the chip capacitor 32 is opposed to the semiconductor element 31.

According to the semiconductor device shown in FIG. 8, when the chip capacitor 32 is provided in the electric power supply circuit to supply electric power to the semiconductor element 31, it is possible to reduce the occurrence of switching noise caused by a large number of switching elements. Therefore, electric power can be stably supplied to the semiconductor element 31.

However, in the semiconductor device shown in FIG. 8, the semiconductor element 31 and the chip capacitor 32 are electrically connected with each other by the wiring pattern 110 and the via 160 which are formed on the multilayered wiring substrate 340. As shown in FIG. 8, this via 160 is formed stepwise so that the multiple wiring patterns 110, which are laminated on each other, can be electrically connected with each other, and the wiring patterns 110 are arranged on the same plane. Therefore, a conductor path to-electrically connect the semiconductor element 31 with the chip capacitor 32 is formed in a zigzag manner. Accordingly, the conductor distance is long and inductance is increased. For the above reasons, it is impossible to sufficiently reduce the occurrence of switching noise.

### SUMMARY OF THE INVENTION

It is an object of the present invention to provide a semiconductor device composed of a multilayered wiring substrate on which a semiconductor element and chip capacitor are mounted, in which a conductor path to electrically connect the semiconductor element with the chip capacitor is formed as short as possible so that the occurrence of switching noise can be sufficiently reduced.

In order to solve the above problems, the present inventors have made investigations and found that the inductance of a conductor path can be reduced when the conductor path to electrically connect a semiconductor element with a chip capacitor, which are mounted on both sides of a multilayered wiring substrate, is formed as linearly as possible. In this way, the inventors accomplished the present invention.

According to the present invention, there is provided a semiconductor device comprising: a multi-layered wiring substrate in which a multiple wiring pattern layers are laminated through insulating layers, the multi-layered wiring substrate having a first, semiconductor element mounting face and a second face opposite to the first face; first connecting pads formed on the first, semiconductor element mounting face of the multi-layered wiring substrate; second connecting pads formed on the second face of the multi-layered wiring substrate; a semiconductor element mounted on and connected to the first connecting pads; a chip-capacitor arranged on and connected to the second connecting pads; an electric power supply circuit including the chip-capacitor for supplying an electric power to the semiconductor element; and conductor paths for electrically connecting the first connecting pads with the second connecting pads, the conductor paths being substantially extended vertically to pass through the through multi-layered wiring substrate so as to reduce the length of the conductor paths at minimum, so that the chip-capacitor is located at the opposite side of the semiconductor element.

According to another aspect of the present invention, there is provided a method of manufacturing a semiconductor device comprising the following steps of: preparing a multi-layered wiring substrate in which multiple wiring pattern layers are laminated through insulating layers, the multi-layered wiring substrate having first and second faces, first connecting pads formed on the first face, and second connecting pads formed on the second face and conductor paths for electrically connecting the first connecting pads with the second connecting pads, the conductor paths penetrating substantially vertically through the multi-layered wiring substrate so as to reduce the length of the conductor paths at minimum; and mounting a semiconductor element on, and electrically connecting it with, the first connecting pads and also mounting a chip-capacitor and electrically connection the chip-capacitor with the second connecting pads, respectively.

In the present invention, when the conductor is formed by a via penetrating the insulating layers which form the multilayered wiring substrate, it is possible to positively form a linear conductive path by a simple method.

The linear conductive path can be positively realized by using a stacked via and/or through-hole via as the via.

When a multilayered wiring substrate is used on which multiple wiring patterns are laminated on both sides of a core substrate through insulating patterns and the laminated wiring patterns are electrically communicated with each other by the vias penetrating the core substrate and insulating layers, it is possible to stably supply electric power to a semiconductor element mounted on the multilayered wiring substrate which is adapted to the structure of arranging components at high density.

According to the present invention, there is provided a chip capacitor on the other side of a multilayered wiring substrate in the closest portion to a semiconductor element mounted on one side of the multilayered wiring substrate, and a conductor path to connect the semiconductor element with the chip capacitor is formed along a perpendicular to the mounted semiconductor element to the other side of the multilayered wiring substrate.

Due to the above structure, it is possible to electrically connect the semiconductor element with the chip capacitor, which are arranged on both sides of the multilayered wiring substrate, by the shortest conductor path. As a result, inductance of the conductor path to electrically connect the semiconductor element with the chip capacitor can be reduced, and the occurrence of switching noise can be sufficiently reduced.

### BRIEF DESCRIPTION OF THE DRAWINGS

In the drawing:

FIGS. 1(a) to 1(d) are schematic illustrations for explaining an embodiment of the method of manufacturing the semiconductor device of the present invention;

FIG. 2 is a sectional view for explaining another embodiment of the semiconductor device of the present invention;

FIGS. 3(a) and 3(b) are schematic illustrations for explaining another embodiment of the method of manufacturing the semiconductor device of the present invention;

FIGS. 4(a) to 4(c) are schematic illustrations for explaining a method of manufacturing a laminated layer film type core substrate used instead of the core substrate shown in FIG. 1(a);

FIG. 5 is a sectional view for explaining another embodiment of the semiconductor device of the present invention;

FIG. 6 is a sectional view for explaining another embodiment of the semiconductor device of the present invention;

FIG. 7 is a schematic illustration for explaining another embodiment of the multilayered wiring substrate used for the semiconductor device of the present invention; and

FIG. 8 is a partial sectional view for explaining a conventional semiconductor device.

### DETAILED DESCRIPTION OF THE PREFERRED EMBODIMENTS

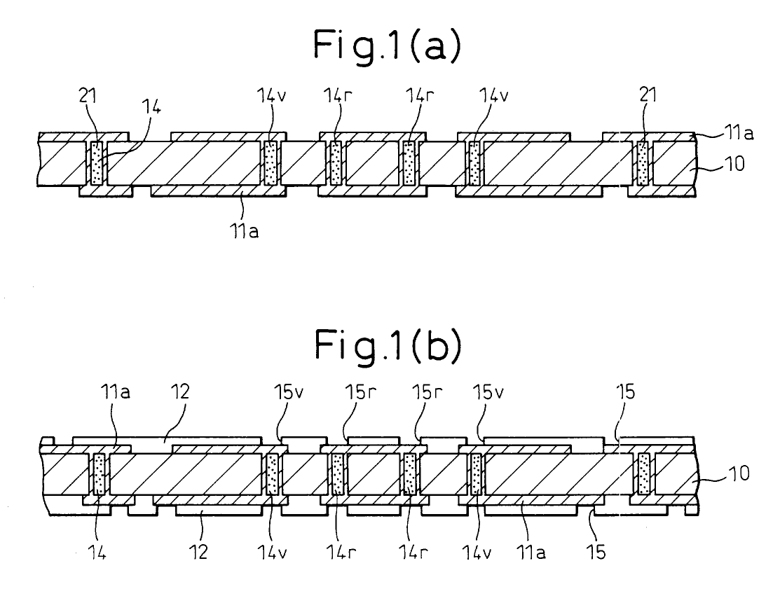

An embodiment of the semiconductor device of the present invention is shown in FIG. 1(d). In the semiconductor device shown in FIG. 1(d), on the other side of the multilayered wiring substrate 34, on one side of which the semiconductor element 31 is mounted, there is provided a chip capacitor 32 at a position directly below the semiconductor element 31. In other words, the chip capacitor 32 is arranged in the direction of a perpendicular to the semiconductor element 31, which is mounted on one side of the multilayered wiring substrate 34, on the other side of the multilayered wiring substrate 34.

In this semiconductor element 31, there are provided an electric power supply terminal, grounding terminal and output terminal which are not shown in the drawing. Through the solder bumps 33, they are correspondingly connected with the connection pad 37v for supplying electric power, connection pad 37r for grounding and connection pad 37s for outputting.

The chip capacitor 32 is connected with the connection pad 38v for supplying electric power and the connection pad 38r for grounding through the solder bumps 36.

The connection pad 38v for supplying electric power and the connection pad 38r for grounding, which are formed on the other side of the multilayered wiring substrate 34, are arranged in the direction of a perpendicular to the connection pad 37v for supplying electric power and the connection pad 37r for grounding to the other side of the multilayered wiring substrate 34.

Further, in the semiconductor device shown in FIG. 1(d), the connection pad 37v for supplying electric power and the connection pad 37r for grounding, which are arranged on one side of the multilayered substrate 34, are respectively electrically connected with the connection pad 38v for supplying electric power and the connection pad 38r for grounding, which are arranged on the other side of the multilayered wiring substrate 34, by the conductor path 35v for supplying electric power and the conductor path 35r for grounding, the profiles of which are linear.

The above conductor path 35v for supplying electric power and the conductor path 35r for grounding are formed along perpendiculars hanging down from the connection pad 37v for supplying electric power and the connection pad 37r for grounding, which are arranged on one side of the multilayered substrate 34, to the other side of the multilayered substrate 34. The above conductor path 35v for supplying electric power and the conductor path 35r for grounding are made by utilizing vias formed on the multilayered wiring substrate 34.

That is, the multilayered wiring substrate 34 is composed as follows. On both sides of the core substrate 10 on which the wiring pattern 11a is formed, two layers of the wiring patterns 11b, 11c are laminated through insulating layers, and the wiring patterns 11a, 11b, 11c are electrically connected with each other through the vias 16 penetrating the insulating layers and through the vias 14 penetrating the core substrate 10. When these vias 14, 16 are put on each other being formed like pillars, the conductor path 35v for supplying electric power and the conductor path 35r for grounding, the profile of which are linear, are formed.

The above vias 14, 16 are formed in the following manner. The via 14 is formed in such a manner that a hollow portion of the through-hole via penetrating the core substrate 10 is filled with the filler 21, and the via 16 is formed in such a manner that a via hole formed on the insulating layer is filled with metal. Therefore, it is possible to put the via 16 on both sides of the via 14 so that the vias, which are put on each other, can be formed like a pillar.

In the semiconductor device shown in FIG. 1(d), the chip capacitor 32 is arranged in the direction of a perpendicular hanging down from the semiconductor element 31, which is mounted on one side of the multilayered wiring substrate 34, to the other side of the multilayered wiring substrate 34. The semiconductor element 31 and the chip capacitor 32 are electrically connected with each other, through the shortest distance, by the conductor path 35v for supplying electric power and the conductor path 35r for grounding which are formed along this perpendicular.

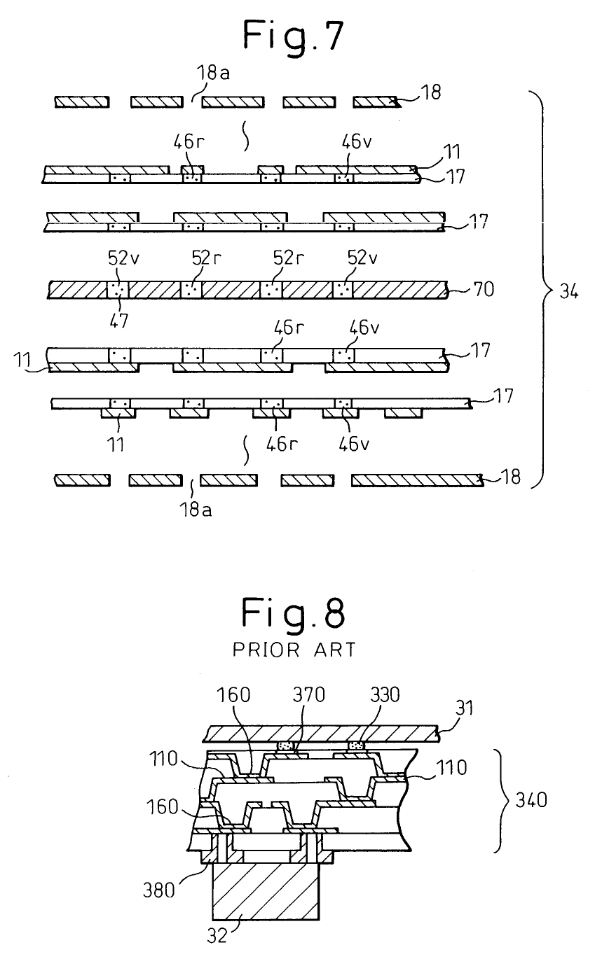

Due to the above structure, compared with the semiconductor device shown in FIG. 8, the semiconductor device shown in FIG. 1(d) is advantageous in that the conductor path to connect the semiconductor element 31 with the chip capacitor 32 can be reduced to as short as possible.

Therefore, inductance of the conductor path can be reduced and the occurrence of switching noise can be sufficiently reduced. As a result, electric power can be stably supplied to the semiconductor element 31.

In this connection, reference numeral 39 is a solder bump which is an external connection terminal for mounting.

The semiconductor device shown in FIG. 1(d) is manufactured in the process shown in FIGS. 1(a) to 1(c).

First of all, the core substrate 10 is formed according to the process shown in FIG. 1(a).

The core substrate 10 is composed of a resin substrate such as a glass epoxy substrate or BT (bismaleimide triazine) substrate. When a resin substrate of about 0.4 mm thickness, which is thinner than the conventional resin substrate of about 0.8 mm thickness used for a core substrate, is used, it is possible to obtain a thinner core substrate 10, which is preferable because length of the conductor path 35v for supplying electric power and also length of the conductor path 35r for grounding, which are finally formed, can be reduced.

After a plurality of through-holes used for forming through-hole vias have been formed on this resin substrate by means of drilling or laser beam machining, electroless copper plating is conducted on the entire face of the resin substrate including inner wall faces of the through-holes. Then, electrolytic copper plating is conducted when the thus formed electroless copper plating layer is used as a feeder layer.

The via 14 is formed by filling the filler 21 into the hollow portion of the through-hole via, on the inner wall face of the through-hole of which the electroless copper plating layer and the electrolytic copper plating layer are formed. Concerning the filler 21, an insulating material such as resin may be used. Alternatively, a conductive resin material may be used in which conductive material such as metallic particles are contained in resin. This filler 21 can be filled in the hollow portion of the through-hole via by the screen printing method. After that, in order to flatten an exposure face of the via 14 in which the filler 21 is filled, polishing may be conducted on a surface of the copper layer including the exposure face of the via 14.

Next, on the entire face including the exposure face of the via 14 in which the filler 21 is filled, electroless copper plating and electrolytic copper plating are conducted so as to form a copper layer. After that, patterning is conducted on the copper layer so as to form wiring patterns 11a, 11a, . . . .

Concerning the patterning method, it is possible to adopt a well-known patterning method. For example, it is possible to adopt a chemical etching method while a resist pattern, which is formed by conducting exposure and development on photosensitive resist coated on a surface of the copper layer, is being used as a mask.

The wiring pattern 11a is formed on both end faces of the via 14 on the thus obtained core substrate 10, and the via 16 can be laminated on each of both end faces of the via 14.

In this connection, the core substrate 10 shown in FIG. 1(a) is composed of a resin substrate. However, thickness of the core substrate 10 may be further reduced by using a highly rigid substrate such as a metallic substrate which is more rigid than the resin substrate. In this case, it is preferable to use a metallic core substrate on which a wiring pattern is formed on the metallic substrate through an insulating layer.

Further, instead of the means for electroless copper plating, a means for spattering or direct plating may be adopted.

Next, on the insulating layer 12 to cover each of the wiring pattern forming faces on which the wiring patterns 11a, 11a, . . . of the core substrate 10 are formed, the via holes 15 used for forming the vias 16 are formed in the process shown in FIG. 1(b).

The insulating layer 12 is made of insulating resin such as polyimide resin, epoxy resin or polyphenylene ether resin. The insulating layer 12 can be formed by adhesion of an insulating film made of insulating resin or by application of insulating resin.

On a bottom face of the via hole 15 formed on the insulating layer 12, the wiring pattern 11a is exposed. This via hole 15 can be formed by means of irradiating a laser beam or etching.

Concerning the via holes 15, 15, . . . , the via hole 15v, in which the via 16v used for forming the conductor path 35v for supplying electric power is formed, and the via hole 15r, in which the via 16r used for forming the conductor path 35r for grounding is formed, are formed directly above or directly below the end face of the corresponding via 14v or 14r.

Further, the wiring patterns 11b and the vias 16 are formed on the insulating layers 12 covering the respective wiring pattern forming faces on the core substrate 10 in the process shown in FIG. 1(c).

In the case where the wiring patterns 11b and the vias 16 are formed, electrolytic copper plating is conducted on the entire face of the insulating layer 12 including the bottom faces and inner wall faces of the via holes 15, 15, . . . in which the electroless copper plating layer formed by means of electroless copper plating is used as a feeder layer, so that via holes 15, 15, . . . are filled with copper, and the copper layer is formed.

Concerning this electroless copper plating, it is preferable to adopt PR electrolytic copper plating in which the anode and cathode are inverted at predetermined periods.

PR electrolytic copper plating is conducted as follows. The anode and cathode, between which a forward electric current to fill copper into the via holes 15, 15, . . . , are inverted at a predetermined period, and a copper layer is formed on the electroless copper plating layer in the via holes 15, 15, . . . by PR to make a reverse electric current flow in the direction opposite to the flowing direction of the forward electric current. After that, DC electrolytic copper plating, in which DC current is made to flow, is conducted on the residual portions in the via holes 15, 15, . . . so that copper is filled in the via holes. In this way, the vias 16, 16, . . . can be formed. The above method is preferable because the via can be formed by sufficiently filling metal even in a recess portion of a small diameter in a predetermined period of time.

Next, patterning is conducted on the copper layer, which is formed on the surface of the insulating layer 12, by a well-known method so that the wiring patterns 11b, 11b, . . . are formed.

In the vias 16 formed in this way, copper is filled in the via holes 15. Therefore, it is possible to laminate vias on the vias 16.

In this case, instead of electroless copper plating in which the entire insulating layer 12 including the bottom faces and inner wall faces of the via holes 15, 15, . . . are plated with copper, the means of spattering or direct plating may be adopted.

When a surface of the insulating layer 12 is mechanically or chemically made rough in the case of forming the wiring pattern 11b, 11b, . . . on the insulating layer 12, the insulating layer 12 and the wiring patterns 11b, 11b, . . . can be made to come into close contact with each other.

After that, when the process shown in FIG. 1(b) and that shown in FIG. 1(c) are repeated, the multilayered wiring substrate 34, on which the wiring patterns 11b, 11c are laminated through the insulating layer, can be formed on the wiring patterns 11a formed on both sides of the core substrate 10.

On this multilayered wiring substrate 34, the conductor paths 35v for supplying electric power, the profiles of which are linear, are formed in such a manner that the vias 14v penetrating the core substrate 10 and the vias 16v, 16v, . . . penetrating the insulating layers are laminated on each other being formed into a pillar shape, and the conductor paths 35r for grounding, the profiles of which are linear, are formed in such a manner that the vias 14r penetrating the core substrate 10 and the vias 16r, 16r, . . . penetrating the insulating layers are laminated on each other being formed into a pillar shape.

On the thus formed multilayered wiring substrate 34, connection pads are formed which are connected with the electrode terminals of the semiconductor element 31 and the chip capacitor 32, and the connection pads 37v, 38v for supplying electric power and the connection pads 37r, 38r for grounding are formed on the end faces of the conductor paths 35v for supplying electric power and the conductor paths 35r for grounding. The above connection pads can be formed by the same method as that of forming the wiring pattern.

The semiconductor element mounting face and the chip capacitor mounting face, on which the connection pads and others are formed, are coated with solder resist 22 except for the connection pads so that the wiring pattern 11c and others can be protected, and then the solder bumps 33, 36 are formed on the connection pads.

On the multilayered wiring substrate 34 composing the semiconductor device shown in FIG. 1(d), the conductor paths 35v for supplying electric power and the conductor paths 35r for grounding are formed in such a manner that the vias 16v, 16r penetrating the insulating layers are successively laminated on the vias 14v, 14r penetrating the core substrate 10. Therefore, linearity of the thus formed conductor paths 35v for supplying electric power and the conductor paths 35r for grounding gets out of order a little within the range of an error caused in the process of laminating the vias 16.

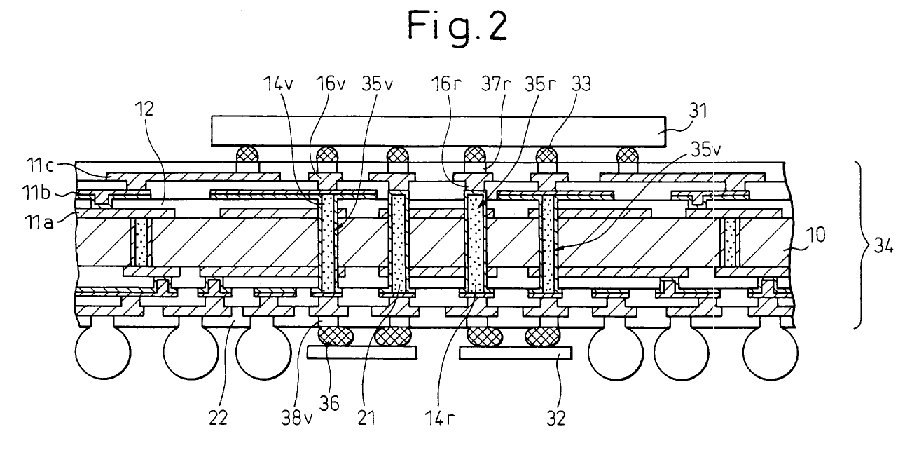

From this viewpoint, there is provided a multilayered wiring substrate 34 composing the semiconductor device as shown in FIG. 3(b). On this multilayered wiring substrate 34, the conductor paths 35v for supplying electric power and the conductor paths 35r for grounding are composed of the vias 19v, 19r which are formed by utilizing through-holes linearly penetrating the core substrate 10 and also penetrating a plurality of insulating layers 12, 12 laminated on both sides of the core substrate 10. Therefore, when the conductor paths 35v for supplying electric power and the conductor paths 35r for grounding are formed, the number of the laminated vias 16v, 16r can be reduced. Accordingly, fluctuation of the linearity caused by the lamination of the vias 16v, 16r can be reduced as much as possible.

The multilayered wiring substrate 34 composing the semiconductor device shown in FIG. 3(b) is made as follows. On both sides of the core substrate 10 on which through-holes are not formed in portions where the vias 19v, 19r are to be formed, the predetermined wiring patterns are formed through the insulating layers 12. After that, as shown in FIG. 3(a), the through-holes 51v, 5lr penetrating the core substrate 10 and the insulating layers 12, 12, . . . are formed. These through-holes 51v, 5lr are formed by means of drilling or laser beam machining.

Next, by utilizing these through-holes 51v, 51r, the vias 19v, 19r are formed in the same manner as that of forming the vias 14 on the core substrate 10 shown in FIG. 1(a).

Further, on the vias 19v, 19r, the pads coming into contact with the electrode terminals of the semiconductor element and the chip capacitor are formed, and the conductor paths 35v for supplying electric power and the conductor paths 35r for grounding are formed.

In the case of the multilayered wiring substrate 34 composing the semiconductor device shown in FIGS. 1 and 3, the conductor paths 35v for supplying electric power and the conductor paths 35r for grounding are formed by utilizing the through-holes formed by means of drilling or laser beam machining.

However, the diameter of a fine through-hole to be formed by means of drilling is limited. Accordingly, the diameter of the conductor path 35v for supplying electric power and the diameter of the conductor path 35r for grounding to be formed are limited.

Further, when thickness of the core member in which the through-holes are formed is large, it is necessary to use a drill of a large diameter because the mechanical strength of the drill must be increased. As a result, the inner diameter of a through-hole to be formed is increased.

On the other hand, when the means of laser beam machining is used, in the case where thickness of the core member in which the through-holes are formed is small, it is possible to form a fine through-hole. However, in the case where thickness of the core member in which the through-holes are formed is large, it is difficult to form a fine through-hole.

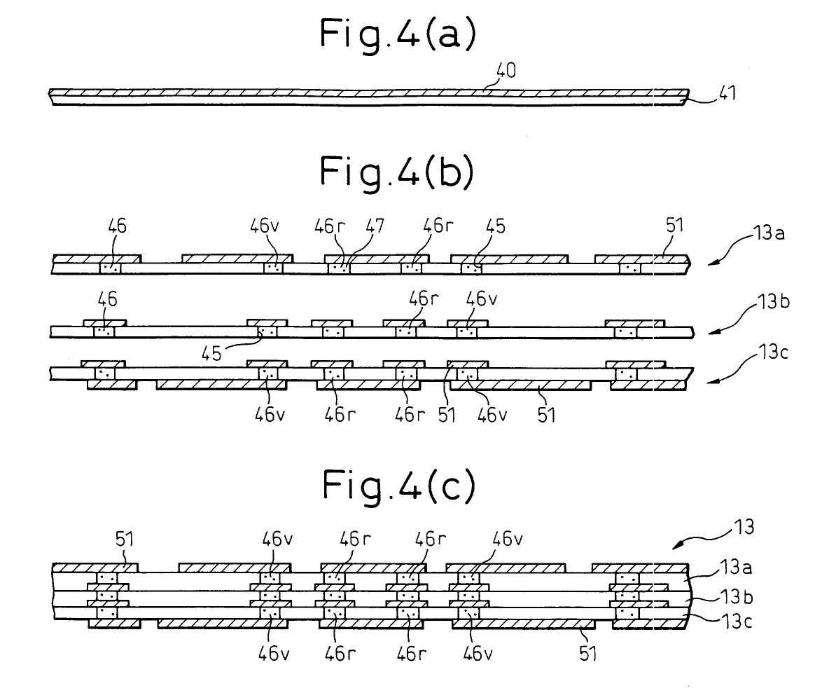

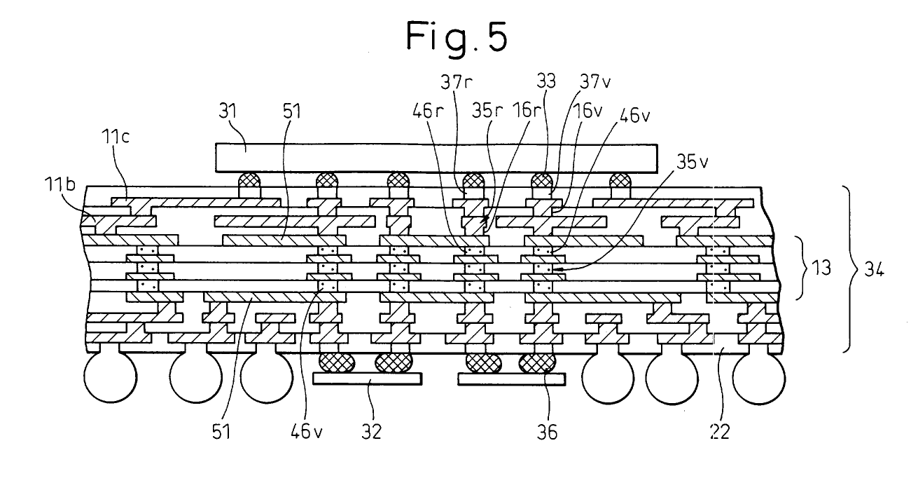

From this viewpoint, there is provided a multilayered wiring substrate 34 composing the semiconductor device as shown in FIGS. 5 and 6. On this multilayered wiring substrate 34, the laminated film type core substrate 13 is used, which will be referred to as a core substrate 13 hereinafter, on which a plurality of films are laminated on each other. Compared with the core substrate 10 on which the multilayered wiring substrate 34 shown in FIGS. 1 and 3 is used, thickness of the thus formed core substrate 13 can be reduced. Therefore, a sufficiently fine through-hole can be formed by means of laser beam machining and so forth.

Therefore, on the multilayered wiring substrate 34 shown in FIGS. 5 and 6, it is possible to form conductor paths 35v for supplying electric power and conductor paths 35r for grounding, the density of which is higher than the density of the multilayered wiring substrate 34 shown in FIGS. 1 and 3.

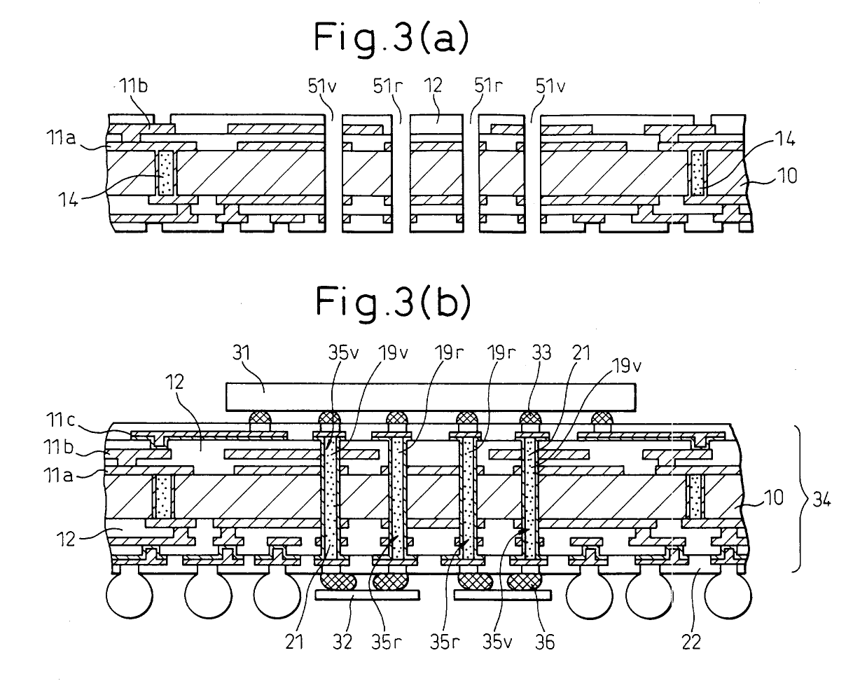

The core substrate 13 composing the multilayered wiring substrate 34 shown in FIG. 5 can be formed in the process shown in FIG. 4.

First, as shown in FIG. 4(a), the film 41 made of polyimide resin, on one face of which the copper foil 40 is bonded, is used, and the via holes 45, from the bottom faces of which the copper foil is exposed, are formed by means of laser beam machining conducted from a predetermined position on the other side of the film 41. After that, the thus formed via holes 45 are filled with the conductive material 47 of metal such as solder, tin, lead or zinc by means of plating so that the vias 46 can be formed. Alternatively, the thus formed via holes 45 are filled with the conductive material 47 such as conductive paste containing metallic particles of these metals so that the vias 46 can be formed. Then, patterning is conducted on the copper foil 40 so that the wiring pattern 51 is formed. The thus formed wiring pattern 51 includes pads formed on the end faces of the vias 46.

A series of operation for forming the vias 46 and the wiring patterns 51 is conducted on a plurality of films. In this way, as shown in FIG. 4(b), a plurality of film substrates 13a, 13b, 13c, are formed, on one side of the film 41 on which the wiring pattern 51 is formed, and at the predetermined positions at which the vias 46 are formed.

Next, the film substrates 13a, 13b, 13c are laminated and thermally fitted to each other with pressure, so that the lamination film type core substrate 13 shown in FIG. 4(c) is formed. At this time, each substrate is positioned so that the vias 46v, 46r can be laminated through the pads being formed into a pillar shape and the vias, the profiles of which are linear, can be formed.

In this case, it is preferable that the wiring patterns 51 are formed on both sides of the film substrate 13c forming one of the outermost layers of the core substrate 13. The wiring pattern 51 formed on one side of the film substrate 13c can be made of the copper foil 40, and the wiring pattern 51 formed on the other side of the film substrate 13c can be made in such a manner that after the vias 46 have been formed, patterning is conducted on a copper layer formed by means of electroless copper plating and electrolytic copper plating.

In this connection, the film substrate 13c may be formed by utilizing the film 41, on both sides of which the copper foil 41 is provided.

When the wiring patterns 11b, 11c are laminated on both sides of the thus formed film type core substrate 13 through the insulating layers 12 in the same process as that shown in FIG. 1(b), the multilayered wiring substrate 34 shown in FIG. 5 can be formed.

Further, when the semiconductor element 31 and the chip capacitor 32 are mounted at the predetermined positions on the multilayered wiring substrate 34, the semiconductor device shown in FIG. 5 can be obtained.

In the semiconductor device shown in FIG. 5, the chip capacitor 32 is arranged in the direction of a perpendicular to the semiconductor element 31, which is mounted on one side of the multilayered wiring substrate 34, to the other side of the multilayered wiring substrate 34. The semiconductor element 31 and the chip capacitor 32 are electrically connected with each other, through the shortest distance, by the conductor path 35v for supplying electric power and the conductor path 35r for grounding which are formed along this perpendicular.

The thickness of the laminated film type core substrate 13 shown in FIG. 4(c) is smaller than thickness of the core substrate 10 shown in FIGS. 1 and 3. Therefore, it is possible to form vias by utilizing the through-holes formed by a drill of a small diameter.

Therefore, as shown in FIG. 6, after the wiring patterns 11b, 11c have been laminated on both sides of the core substrate 13 through the insulating layer 12, the vias 19v, 19r may be formed by utilizing the through-holes formed by means of drilling.

In this case, after the vias 19v, 19r have been formed, the connection pads 37v, 37r coming into contact with the electrode terminals of the semiconductor element 31 or the connection pads 38v, 38r coming into contact with the terminals of the chip capacitor 32 are formed on both end faces of the vias 19v, 19r. Due to the foregoing, the conductor paths 35v for supplying electric power and the conductor paths 35r for grounding can be formed by the vias 19v, 19r.

In this connection, like reference characters are used to indicate like parts in FIGS. 1, 3, 5 and 6, and the detailed explanations are omitted here.

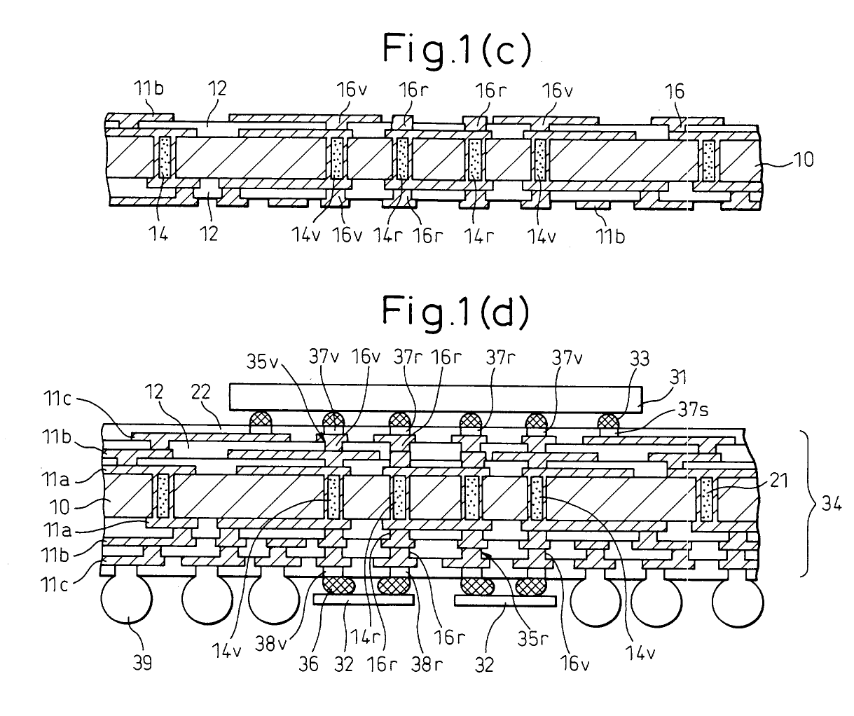

The vias 19v, 19r composing the multilayered wiring substrate 34 of the semiconductor device shown in FIGS. 3 and 6 are formed by utilizing the through-hole vias penetrating the multilayered wiring substrate 34. However, the vias 19v, 19r may be formed by utilizing the through-hole vias penetrating portions of the core substrate 10 and the insulating layers 12, 12, . . . , as shown in FIG. 2.

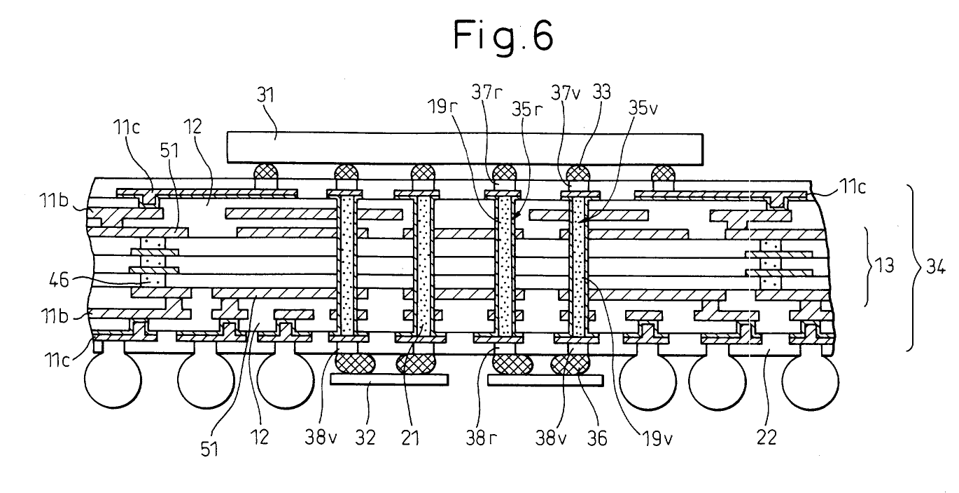

The multilayered wiring substrate 34 composing the semiconductor device shown in FIGS. 1 to 6 may be composed of the core substrate 70 made of ceramics or glass epoxy resin as shown in FIG. 7.

The multilayered wiring substrate 34 on which the core substrate 70 shown in FIG. 7 is provided can be formed when the film substrates 17, 17, . . . and the protective films 18 are laminated and thermally fitted onto both sides.

On this core substrate 70, the vias 52v, 53r are formed. These vias 52v, 53r are formed in such a manner that the conductive material 47 is filled into the through-holes penetrating a substrate made of ceramics or glass epoxy.

Further, on the respective film substrates 17, 17, . . . , the vias 46v, 46r penetrating the film are formed, and further the wiring pattern 11 is formed on one side of the film. These vias and wiring patterns can be formed in the same manner as that of the film substrate 13a and others shown in FIG. 4(b).

The protective film 18 is composed in such a manner that an adhesive layer made of thermoplastic resin is provided on one side of a thermoplastic resin layer, and through-holes 18a in which external connection terminals such as solder balls are provided are formed.

When the core substrate 70, film substrates 17, 17, . . . and protective films 18, 18 are laminated and thermally fitted to each other, positioning is conducted so that the vias 46v, 46r formed on the respective film substrates 17, 17, . . . and the vias 52v, 52r formed on the core substrate 10 can be linearly put on top of each other. In this way, the linear conductor paths for supplying electric power can be formed by the vias 46v, . . . , 52v, and the conductor paths for grounding can be formed by the vias 46r, . . . , 52r.

On the multilayered wiring substrate 34 formed as described above, multiple layers of the wiring patterns 11 are laminated on both sides of the core substrate 70 with the films. Therefore, the thus formed multilayered wiring substrate 34 can be made thinner than the multilayered wiring substrate 34 shown in FIGS. 1 to 6. Accordingly, both the length of the conductor path 35v for supplying electric power and the length of the conductor path 35r for grounding can be further reduced.

Especially when the core substrate 10 is composed of a ceramic substrate, the mechanical strength of the multilayered wiring substrate 34 can be enhanced.

It should be understood by those skilled in the art that the foregoing description relates to only some of preferred embodiments of the disclosed invention, and that various changes and modifications may be made to the invention without departing the sprit and scope thereof.

For example, the above-mentioned embodiments can be changed into various embodiments within the scope of the present invention. It is possible to use pins such as nail head pins instead of the solder bumps which are used as external connection terminals used in the embodiments.

In the semiconductor device of the present invention, as the semiconductor element and the chip capacitor are connected with each other by the linear conductor paths, the connection can be accomplished through the shortest distance and its inductance can be reduced. Accordingly, the occurrence of switching noise can be effectively reduced and electric power can be stably supplied to the semiconductor element. Therefore, the present invention is effective for integrating components with high density and enhancing a processing speed.

1. A semiconductor device comprising:
a multi-layered wiring substrate in which multiple wiring pattern layers are laminated through insulating layers, said multi-layered wiring substrate having a first, semiconductor element mounting face and a second face opposite to said first face;
first connecting pads formed on said first, semiconductor element mounting face of the multi-layered wiring substrate;
second connecting pads formed on said second face of the multi-layered wiring substrate;
a semiconductor element mounted on and connected to said first connecting pads;
a chip-capacitor arranged on and connected to said second connecting pads;
an electric power supply circuit including said chip-capacitor for supplying an electric power to said semiconductor element; and
conductor paths for electrically connecting said first connecting pads with said second connecting pads, said conductor paths being extended substantially vertically and penetrate through said multi-layered wiring substrate so as to reduce the length of the conductor paths to a minimum, so that the chip-capacitor is located at the opposite side of said semiconductor element.

2. A semiconductor device as set forth in claim 1, wherein said conductor paths comprise vias, each of which penetrate through the insulating layers for forming said multi-layered wiring substrate.

3. A semiconductor device as set forth in claim 2, wherein each of said vias is a stacked via or through-hole via.

4. A semiconductor device as set forth in claim 1, wherein said multi-layered wiring substrate comprises:
a core substrate having first and second faces thereof; and
wiring pattern layers laminated in multiple through insulating layers on said first and second faces of the core substrate, respectively; and
second vias penetrating through said core substrate for mutually connecting said wiring pattern layers.

5. A semiconductor device as set forth in claim 1, wherein said multi-layered wiring substrate comprises:
a core substrate having first and second faces thereof; and
wiring pattern layers laminated in multiple through insulating layers on said first and second faces of the core substrate, respectively; and
second vias penetrating through said core substrate and said insulating layers for mutually connecting said wiring pattern layers.

6. A method of manufacturing a semiconductor device comprising the following steps of:
preparing a multi-layered wiring substrate in which a multiple wiring pattern layers are laminated through insulating layers, said multi-layered wiring substrate having first and second faces, first connecting pads formed on said first face, and second connecting pads formed on said second face and conductor paths for electrically connecting said first connecting pads with said second connecting pads, said conductor paths penetrating substantially vertically through said multi-layered wiring substrate so as to reduce the length of the conductor paths to a minimum; and
mounting a semiconductor element on and electrically connecting with said first connecting pads and also mounting a chip-capacitor and electrically connecting with said second connecting pads, respectively.

7. A method as set forth in claim 6, wherein each of said conductor paths for electrically connecting said first connecting pads with said second connecting pads is formed vias penetrating said respective insulating layers when said insulating layers are laminated to form said multi-layered wiring substrate.

8. A method as set forth in claim 6, wherein each of said vias is a stacked-via or through-hole via.

9. A method as set forth in claim 6, wherein said multi-layered wiring substrate comprises: a core substrate having first and second faces thereof; wiring pattern layers laminated in multiple through insulating layers on said first and second faces of the core substrate, respectively; and second vias penetrating through said core substrate for mutually connecting said wiring pattern layers.

10. A method as set forth in claim 6, wherein said multi-layered wiring substrate comprises; a core substrate having first and second faces thereof; wiring pattern layers laminated in multiple through insulating layers on said first and second faces of the core substrate, respectively; and second vias penetrating through said core substrate and said insulating layers for mutually connecting said wiring pattern layers.
